(19) United States
(12) Patent Application Publication
(10) Pub. No.: US 2013/0026514 A1
(43) Pub. Date: Jan. 31, 2013

(54) LIGHT EMITTING DEVICE

(71) Applicants: Wei-Ping Lin, Taipei (TW); Izu-Han Lin, Hsinchu (TW)

(72) Inventors: Wei-Ping Lin, Taipei (TW); Izu-Han Lin, Hsinchu (TW)

(21) Appl. No.: 13/189,933

(22) Filed: Jul. 25, 2011

(51) Int. Cl. H01L 33/50

(52) U.S. Cl. 257/98; 257/E33.061

(57) ABSTRACT

The invention provides a light emitting device. A light emitting device includes a light emitting component capable of radiating a light. A first fluorescent layer is capable of radiating a first light of a first wavelength range while being excited by the light. A second fluorescent layer is capable of radiating a second light of a second wavelength range while being excited by the light. A first fluorescent layer is between the light emitting component and the second fluorescent layer, and the first wavelength range is longer than the second wavelength range.

### BACKGROUND OF THE INVENTION

1. Field of the Invention

The present invention relates to a light emitting device, and in particular, to fluorescent layer arrangement of a light emitting device for improving the color rendering index (CRI) value.

2. Description of the Related Art

A conventional white light emitting diode (LED) can be made by mixing red-emitting, green-emitting, and blue-emitting fluorescent layers, by using an ultraviolet (UV) LED to stimulate a white-emitting fluorescent layer, or by using a blue-emitting LED that excites a yellow-emitting fluorescent layer. However, the conventional white light LED has a re-absorption effect because a long-wavelength fluorescent layer may not only absorb light radiated from an LED chip, but also absorb a radiated light radiated from a short-wavelength fluorescent layer. The re-absorption effect leads to problems such as spectra shape changes, decay of color rendering index (CRI) value and difficulties in proper color mixing.

Thus, a novel light emitting device having a reduced re-absorption effect and improved color rendering index (CRI) value is desired.

### BRIEF SUMMARY OF INVENTION

A light emitting device is provided. An exemplary embodiment of a light emitting device comprises a light emitting component capable of radiating a light. A first fluorescent layer is capable of radiating a first light of a first wavelength range while being excited by the light. A second fluorescent layer is capable of radiating a second light of a second wavelength range while being excited by the light. A first fluorescent layer is between the light emitting component and the second fluorescent layer, and the first wavelength range is longer than the second wavelength range.

Another exemplary embodiment of a light emitting device comprises a light emitting component capable of radiating a light. A first fluorescent layer is capable of radiating a first light of a first wavelength range while being excited by the light. A second fluorescent layer is capable of radiating a second light of a second wavelength range while being excited by the light. A first fluorescent layer is between the light emitting component and the second fluorescent layer, and the first wavelength range is longer than the second wavelength range. A third fluorescent layer is disposed between the first and second fluorescent layers, wherein the third fluorescent layer is capable of radiating a third light of a third wavelength range while being excited by the light, and the third wavelength range is between the first and second wavelength ranges.

Yet another exemplary embodiment of a light emitting device comprises a light emitting component capable of radiating a light. A first fluorescent layer disposed on the light emitting component, is capable of radiating a first light of a first wavelength range while being excited by the light. A second fluorescent layer is capable of radiating a second light of a second wavelength range while being excited by the light. A first fluorescent layer is between the light emitting component and the second fluorescent layer, and the first wavelength range is longer than the second wavelength range.

Still yet another exemplary embodiment of a light emitting device comprises a light emitting component capable of radiating a light. A first fluorescent layer is capable of radiating a first light of a first wavelength range while being excited by the light. A second fluorescent layer is capable of radiating a second light of a second wavelength range while being excited by the light. A transparent layer is disposed on the second fluorescent layer. A first fluorescent layer is between the light emitting component and the second fluorescent layer, and the first wavelength range is longer than the second wavelength range

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 is a cross section view showing one exemplary embodiment of a light emitting device of the invention.

FIG. 2 is a cross section view showing another exemplary embodiment of a light emitting device of the invention.

FIG. 3 is a cross section view showing yet another exemplary embodiment of a light emitting device of the invention.

FIG. 4 is a cross section view showing still yet another exemplary embodiment of a light emitting device of the invention.

FIG. 5 is a cross section view showing still yet another exemplary embodiment of a light emitting device of the invention.

FIG. 6 illustrates a color rendering index (CRI) value comparison between the conventional light emitting diode (LED) and one exemplary embodiment of a light emitting device of the invention.

### DETAILED DESCRIPTION OF INVENTION

The following description is of a mode for carrying out the invention. This description is made for the purpose of illustrating the general principles of the invention and should not be taken in a limiting sense. The scope of the invention is best determined by reference to the appended claims. Wherever possible, the same reference numbers are used in the drawings and the descriptions to refer the same or like parts.

The present invention will be described with respect to particular embodiments and with reference to certain drawings, but the invention is not limited thereto and is only limited by the claims. The drawings described are only schematic and are non-limiting. In the drawings, the size of some of the elements may be exaggerated and not drawn to scale for illustrative purposes. The dimensions and the relative dimensions do not correspond to actual dimensions to practice the invention.

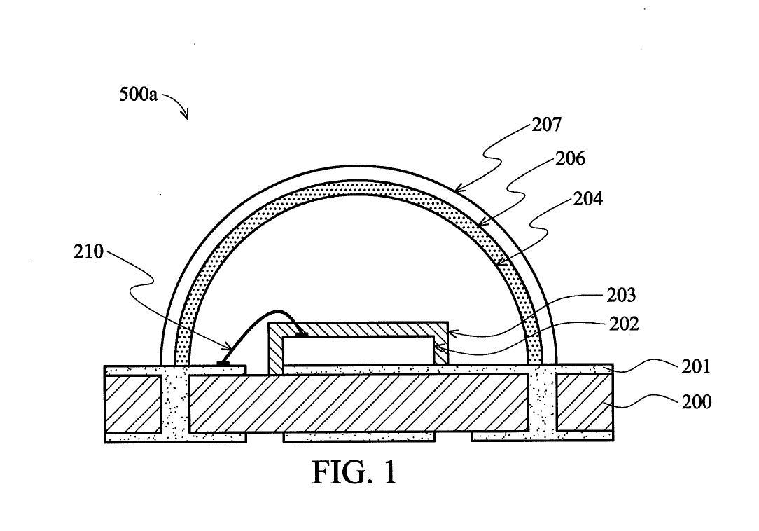

Embodiments of the invention provides a light emitting device composed by arranging a fluorescent layer to radiate a light of a long wavelength range as an inner fluorescent layer and a fluorescent layer to radiate a light of a short wavelength range as an outer fluorescent layer while the first and second fluorescent layers are excited by the light radiated from the light emitting component, so that the light emitting device has an improved color rendering index (CRI). FIGS. 1 to 5 are a cross section views showing various exemplary embodiments of a light emitting device. FIG. 1 is a cross section view showing one exemplary embodiment of a light emitting device 500a. As shown in FIG. 1, the light emitting device 500a comprises a substrate 200. In one embodiment, the light emitting device 500a is a white light emitting diode (LED). In one embodiment, the substrate 200 having conductive line patterns 201 disposed thereon may serve as a carrier supporting a subsequent mounted light emitting component. A light emitting component 202, for example, a light emitting diode (LED) chip, is disposed on the substrate 200, wherein one electrode of the light emitting component 202 is connected to one of the conductive line patterns 201 and the other electrode of the light emitting component 202 is connected to another one of the conductive line patterns 201 through the wiring 210 using a wire bonding method. In one embodiment, the light emitting component 202 may be capable of radiating a light of a wavelength range belonging to blue light (400 nm to 480 nm) or ultraviolet (UV) light (less than 400 nm).

As shown in FIG. 1, a first fluorescent layer 203 is disposed on the light emitting component 202. A transparent medium 204 is disposed on the light emitting component 202, the first fluorescent layer 203 and a portion of the substrate 200. In one embodiment, the transparent medium 204 is provided as a passivation medium for the underlying first fluorescent layer 203. Also, the transparent medium 204 may allow light radiated from the light emitting component 202 to penetrate to the outside environment. In one embodiment, the transparent medium 204 may comprise resin. In one embodiment, the transparent medium 204 may have a hemispheric shape. The light emitting device 500a comprises a second fluorescent layer 206 disposed on the transparent medium 204. In one embodiment, the first fluorescent layer 203 and the second fluorescent layer 206 are separated from each other by the transparent medium 204. Alternatively, the second fluorescent layer 206 may be disposed on the first fluorescent layer 203. In one embodiment, the first fluorescent layer 203 may be capable of radiating a light of a long-wavelength range, and the second fluorescent layer 206 may be capable of radiating a light of a short-wavelength range, which is shorter than the long-wavelength range of a light radiated from the first fluorescent layer 203 while the first and second fluorescent layers 203 and 206 are excited by the light radiated from the light emitting component 202. For example, the first fluorescent layer 203 is capable of radiating the light of a wavelength range between 580 nm and 650 nm, and the second fluorescent layer 206 is capable of radiating the light of the wavelength range is between 510 nm and 580 nm. Also, the light emitting component 202 may be capable of radiating a light of a wavelength range shorter than the long-wavelength range and the short-wavelength range. In one embodiment, the first fluorescent layer 203 is capable of radiating red fluorescence (580 nm to 650 nm) and the second fluorescent layer 206 is capable of radiating yellow fluorescence (545 nm to 580 nm) while the first and second fluorescent layers 203 and 206 are excited by blue light (400 nm to 480 nm) or ultraviolet (UV) light (less than 400 nm) radiated from the light emitting component 202. Alternatively, the first fluorescent layer 203 is capable of radiating yellow fluorescence (545 nm to 580 nm) and the second fluorescent layer 206 is capable of radiating green fluorescence (510 nm to 545 nm) while the first and second fluorescent layers 203 and 206 are excited by blue light (400 nm to 480 nm) or ultraviolet (UV) light (less than 400 nm) radiated from the light emitting component 202. The light emitting device 500a further comprises a transparent layer 207 disposed on the second fluorescent layer 206. In one embodiment, the transparent layer 207 is provided as a passivation layer for the underlying second fluorescent layer 206. Also, the transparent layer 207 may allow light radiated from the light emitting component 202 to penetrate to the outside environment. In one embodiment, the transparent layer 207 may comprise resin.

The light emitting device 500a is composed by arranging the first fluorescent layer 203 capable of radiating a light of a long-wavelength range, as an inner fluorescent layer and the second fluorescent layer 206 capable of radiating a light of a short-wavelength range, as an outer fluorescent layer while the first and second fluorescent layers 203 and 206 are excited by the light radiated from the light emitting component 202. When the light emitting device 500a is lighted, light radiated from the LED 202 may excite the inner fluorescent layer (the first fluorescent layer 203) firstly to radiate a light of a wavelength range longer than an absorption wavelength range of the outer fluorescent layer (the second fluorescent layer 206). Therefore, the light radiated from the inner fluorescent layer (the first fluorescent layer 203) may be free from being absorbed by the outer fluorescent layer (the second fluorescent layer 206). The re-absorption problem can be reduced. Additionally, the first fluorescent layer 203 and the second fluorescent layer 206 are separated from each other by the transparent medium 204. Therefore, the probability of the light radiated from outer fluorescent layer (the second fluorescent layer 206) to be absorbed by the inner fluorescent layer (the first fluorescent layer 203) is reduced. Thus, the light radiated from each fluorescent layer may be free from the re-absorption effect. The light emitting device has an improved color rendering index (CRI) value.

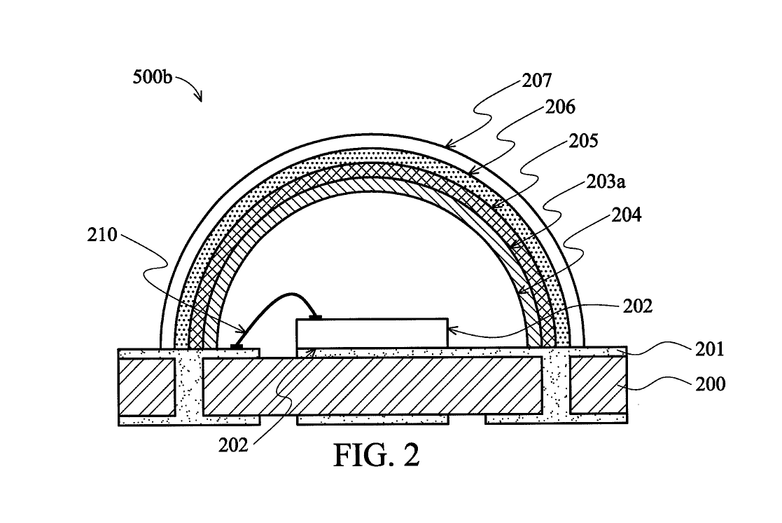

FIGS. 2-5 are cross section views showing various exemplary embodiments of a light emitting device 500b-500e, respectively. The light emitting devices 500b-500e are respectively composed by arranging three fluorescent layers. The three fluorescent layers comprises a first fluorescent layer capable of radiating a light of a long-wavelength range, as an inner fluorescent layer, a second fluorescent layer capable of radiating a light of a short-wavelength range, as an outer fluorescent layer, and a third fluorescent layer capable of radiating a light of a middle-wavelength range while the first, second and third fluorescent layers are excited by the light radiated from the light emitting component. Light radiated from the inner fluorescent layer may have a wavelength range longer than an absorption wavelength range of the outer fluorescent layer. FIG. 2 is a cross section view showing another exemplary embodiment of a light emitting device 500b. As shown in FIG. 2, the light emitting device 500b comprises a substrate 200. In one embodiment, the light emitting device 500b is a white light emitting diode (LED). In one embodiment, the substrate 200 having conductive line patterns 201 disposed thereon may serve as a carrier supporting a subsequent mounted light emitting device. A light emitting component 202, for example, a light emitting diode (LED) chip, is disposed on the substrate 200, wherein one electrode of the light emitting component 202 is connected to one of the conductive line patterns 201 and the other electrode of the light emitting component 202 is connected to another one of the conductive line patterns 201 through the wiring 210 using a wire bonding method. In one embodiment, the light emitting component 202 may radiate blue light or ultraviolet (UV) light.

As shown in FIG. 2, a transparent medium 204 is disposed on the light emitting component 202 and a portion of the substrate 200. In one embodiment, the transparent medium 204 may have a hemispheric shape. In one embodiment, the transparent medium 204 is provided as a passivation medium for the underlying light emitting component 202. Also, the transparent medium 204 may allow light radiated from the light emitting component 202 to penetrate to the outside environment. In one embodiment, the transparent medium 204 may comprise resin. In this embodiment, a first fluorescent layer 203a, a second fluorescent layer 206 and a third fluorescent layer 205 are disposed on the transparent medium 204. The first fluorescent layer 203a is disposed on the transparent medium 204. The second fluorescent layer 206 is disposed outside of the first fluorescent layer 203a. Additionally, the third fluorescent layer 205 is disposed between the first and second fluorescent layers 203a and 206. The third fluorescent layer 205 is disposed on the first fluorescent layer 203a and the second fluorescent layer 206 is disposed on the third fluorescent layer 205. In this embodiment, the first fluorescent layer 203a, the second fluorescent layer 206 and the third fluorescent layer 205 are separated from the light emitting component 202. In one embodiment, the first fluorescent layer 203a may radiate a light of a long-wavelength range, the second fluorescent layer 206 may radiate a light of a short-wavelength range, and the third fluorescent layer 205 may radiate a light of a middle-wavelength range designed between the long-wavelength range and short-wavelength range while the first, second and third fluorescent layers 203a, 206 and 205 are excited by the light radiated from the light emitting component. In one embodiment, the first fluorescent layer 203a is capable of radiating red fluorescence (580 nm to 650 nm), the second fluorescent layer 206 is capable of radiating green fluorescence (510 nm to 545 nm), and the third fluorescent layer 205 is capable of radiating yellow fluorescence (545 nm to 580 nm) while the first, second and third fluorescent layers 203a, 206 and 205 are excited by blue light (400 nm to 480 nm) or ultraviolet (UV) light (less than 400 nm) radiated from the light emitting component. Similarly, the light emitting device 500b further comprises a transparent layer 207 disposed on the second fluorescent layer 206. In one embodiment, the transparent layer 207 is provided as a passivation layer for the underlying first fluorescent layer 203a, the second fluorescent layer 206 and the third fluorescent layer 205. Also, the transparent layer 207 may allow light radiated from the light emitting component 202 to penetrate to the outside environment. In one embodiment, the transparent layer 207 may comprise resin.

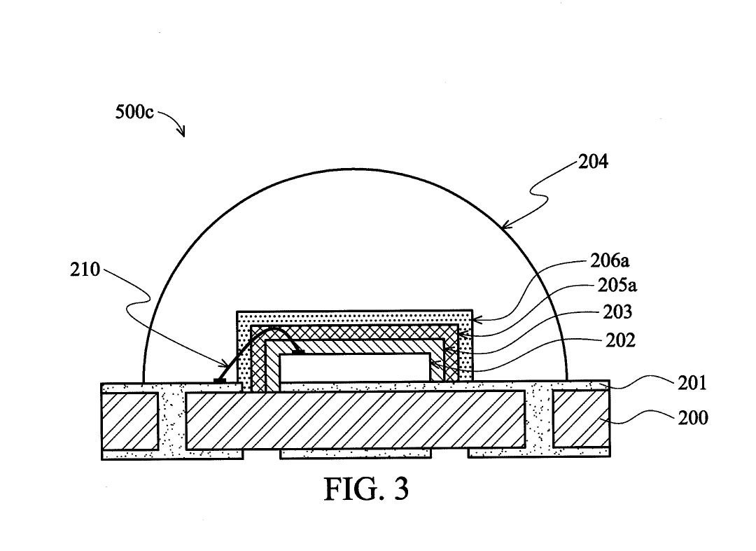

Alternatively, the three fluorescent layers may be collectively disposed between the light emitting component 202 and the transparent medium 204. FIG. 3 is a cross section view showing yet another exemplary embodiment of a light emitting device 500c. As shown in FIG. 3, the light emitting device 500c comprises a first fluorescent layer 203 is disposed on the light emitting component 202, a third fluorescent layer 205a is disposed on the first fluorescent layer 203 and a second fluorescent layer 206a is disposed on the third fluorescent layer 205. Therefore, the second fluorescent layer 206 may be only passivated by the transparent medium 204.

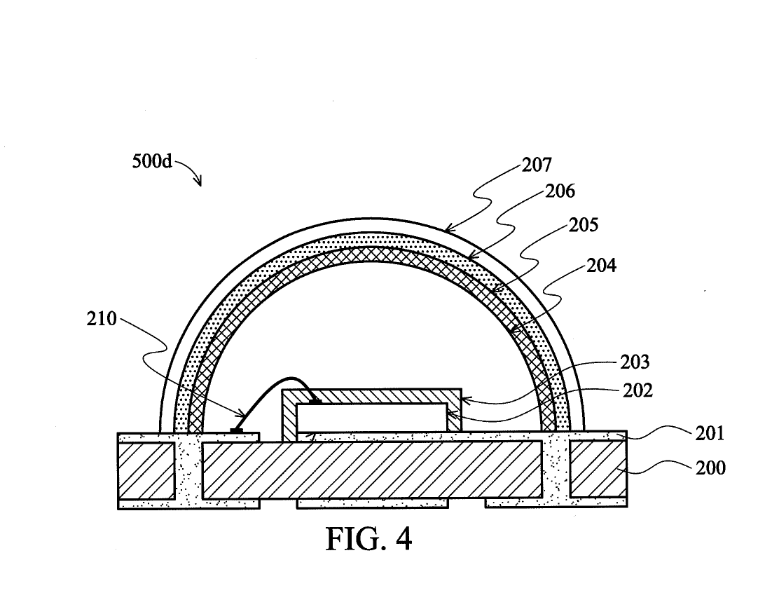

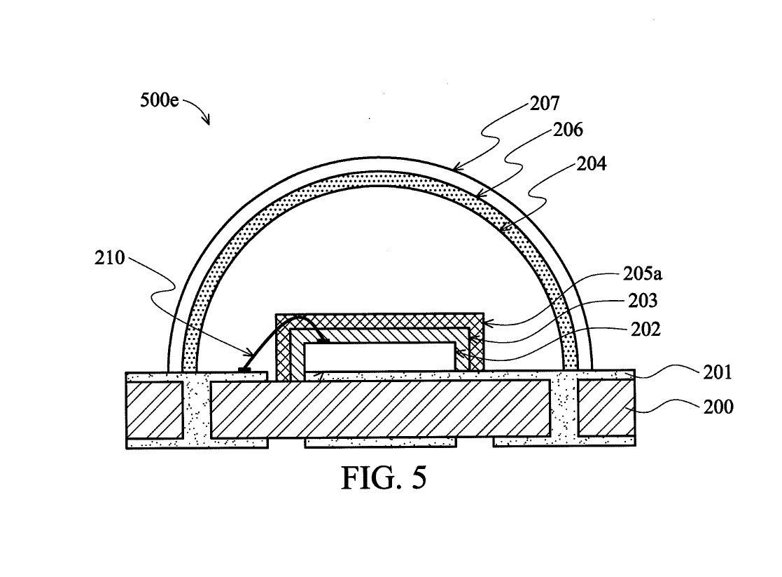

Alternatively, any two adjacent fluorescent layers may be separated from each other by the transparent medium 204. FIGS. 4 and 5 are cross section view showing other exemplary embodiments of a light emitting device 500d and 500e. As shown in FIG. 4, the differences between the light emitting device 500b and the light emitting device 500d are that the first fluorescent layer 203 is disposed on light emitting component 202, and the first fluorescent layer 203 is separated from the third fluorescent layer 205 by the transparent medium 204. As shown in FIG. 5, the differences between the light emitting device 500b and the light emitting device 500e are that the first fluorescent layer 203 is disposed on the light emitting component 202, and the third fluorescent layer 205a is disposed on the first fluorescent layer 203. Also, the third fluorescent layer 205a is separated from the second fluorescent layer 206 by the transparent medium 204.

The light emitting devices 500b-500e are respectively composed by arranging the first fluorescent layer to radiate a light of a long-wavelength range as an inner fluorescent layer and the second fluorescent layer to radiate a light of a short-wavelength range as an outer fluorescent layer and the third fluorescent layer to radiate a light of a middle-wavelength range while the first, second and third fluorescent layers are excited by the light radiated from the light emitting component. When the light emitting device 500b-500e is lighted, light radiated from the LED 202 may firstly excite the inner fluorescent layer to radiate a light of a wavelength range longer than an absorption wavelength range of the adjacent outer fluorescent layer. Therefore, the light radiated from the inner fluorescent layer may be free from being absorbed by the outer fluorescent layer. The re-absorption problem can be reduced. Additionally, embodiments of the light emitting devices 500a, 500d and 500e are respectively composed by arranging two adjacent fluorescent layers separated from each other by the transparent medium 204. Therefore, the probability of the light radiated from the outer fluorescent layer being absorbed by the inner fluorescent layer is further reduced. Thus, light radiated from each fluorescent layer is substantial free from the re-absorption effect. The light emitting device has an improved color rendering index (CRI) value.

TABLE 1
A color rendering index (CRI) value comparison between the
conventional light emitting diode (LED) and one exemplary
embodiment of a light emitting device 500a of the invention,
which are both fabricated as warm white light LED and a
correlated color temperature (CCT) of 2500 K to 3000 K.

| | Comparison 1 | | Comparison 2 | | Comparison 3 | |
|---|---|---|---|---|---|---|
| | CCT | | CCT | | CCT | |
| | (K) | CRI | (K) | CRI | (K) | CRI |
| light emitting | 2552 | 86.01 | 2750 | 85.02 | 2844 | 84.11 |
| device 500a | | | | | | |
| conventional LED | 2599 | 81.36 | 2761 | 79.01 | 2827 | 79.62 |
| Standard illuminants | 2560 | 100 | 2760 | 100 | 2830 | 100 |

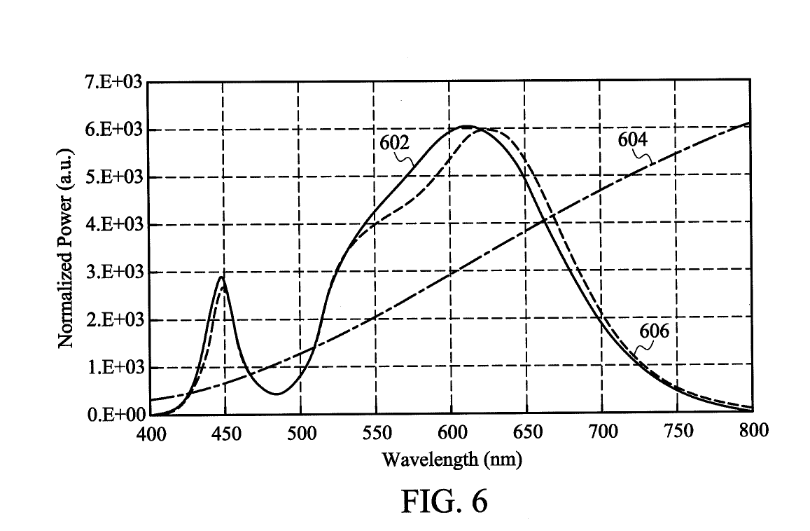

Table 1 illustrates a color rendering index (CRI) value comparison between the conventional light emitting diode (LED) and one exemplary embodiment of a light emitting device 500a of the invention, which are both fabricated as warm white light LEDs and a correlated color temperature (CCT) of 2800K to 3000K. FIG. 6 illustrates a color rendering index (CRI) comparison curve between the conventional light emitting device (curve 602) and one exemplary embodiment of a light emitting device 500a (curve 606) of the invention. The light emitting device 500a for a CRI testing sample of Table 1 and FIG. 6 comprises a blue light LED chip, a red fluorescent layer as a first fluorescent layer, and a yellow fluorescent layer as a second fluorescent layer. The first fluorescent layer is disposed on the LED chip. The second fluorescent layer is disposed on the first fluorescent layer. Further, the first and second fluorescent layers contain a silicone glue. Differences between the conventional light emitting device and the light emitting device 500a are that the conventional light emitting device comprises a yellow fluorescent layer as a first fluorescent layer and a red fluorescent layer as a second fluorescent layer. As shown in Table 1 and FIG. 6, compared with the conventional light emitting device (curve 602), the CRI value of the light emitting device 500a (curve 606) is more close to the standard illuminants (curve 604). The light emitting device 500a shows an improved color rendering index (CRI) value. Similarly, the light emitting devices 500b-500e show an improved color rendering index (CRI) value due to the arrangement of the fluorescent layers because the light radiated from the inner fluorescent layer is free from being absorbed by the outer fluorescent layer while the fluorescent layers are excited by the light radiated from the light emitting component.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A light emitting device, comprising:
a light emitting component capable of radiating a light;
a first fluorescent layer capable of radiating a first light of a first wavelength range while being excited by the light; and
a second fluorescent layer capable of radiating a second light of a second wavelength range while being excited by the light;
wherein a first fluorescent layer is between the light emitting component and the second fluorescent layer, and the first wavelength range is longer than the second wavelength range.

2. The light emitting device as claimed in claim 1, wherein the first fluorescent layer is disposed on the light emitting component.

3. The light emitting device as claimed in claim 1, further comprising a third fluorescent layer disposed between the first and second fluorescent layers, wherein the third fluorescent layer is capable of radiating a third light of a third wavelength range while being excited by the light, and the third wavelength range is between the first and second wavelength ranges.

4. The light emitting device as claimed in claim 1, further comprising a transparent medium disposed on the light emitting component.

5. The light emitting device as claimed in claim 2, wherein the transparent medium is disposed on the first fluorescent layer, and the second fluorescent layer is disposed on the transparent medium.

6. The light emitting device as claimed in claim 3, further comprising a transparent medium disposed on the light emitting component.

7. The light emitting device as claimed in claim 6, wherein the second fluorescent layer is disposed on the third fluorescent layer, the third fluorescent layer is disposed on the first fluorescent layer, and the first fluorescent layer is disposed on the transparent medium.

8. The light emitting device as claimed in claim 6, wherein the transparent medium is disposed on the second fluorescent layer, the second fluorescent layer is disposed on the third fluorescent layer, and the third fluorescent layer is disposed on the first fluorescent layer.

9. The light emitting device as claimed in claim 6, wherein the second fluorescent layer is disposed on the third fluorescent layer, the third fluorescent layer is disposed on the transparent medium, and the transparent medium is disposed on the first fluorescent layer.

10. The light emitting device as claimed in claim 6, wherein the second fluorescent layer is disposed on the transparent medium, the transparent medium is disposed on the third fluorescent layer, and the third fluorescent layer is disposed on the first fluorescent layer.

11. The light emitting device as claimed in claim 1, further comprising a transparent layer disposed on the second fluorescent layer.

12. The light emitting device as claimed in claim 1, wherein the light emitting component is capable of radiating the light of a fourth wavelength range shorter than the first and second wavelength ranges.

13. The light emitting device as claimed in claim 1, wherein the light passes through the first and second fluorescent layers in sequence.

14. The light emitting device as claimed in claim 1, wherein the first wavelength range is between 580 nm and 650 nm, the second wavelength range is between 545 nm and 580 nm.

15. The light emitting device as claimed in claim 1, wherein the first wavelength range is between 545 nm and 580 nm, the second wavelength range is between 510 nm and 545 nm.

16. The light emitting device as claimed in claim 3, wherein the first wavelength range is between 580 nm and 650 nm, the second wavelength range is between 510 nm and 545 nm, and the third wavelength range is between 545 nm and 580 nm.

17. A light emitting device, comprising:
a light emitting component capable of radiating a light;
a first fluorescent layer disposed on the light emitting component, capable of radiating a first light of a first wavelength range while being excited by the light; and
a second fluorescent layer capable of radiating a second light of a second wavelength range while being excited by the light;
wherein a first fluorescent layer is between the light emitting component and the second fluorescent layer, and the first wavelength range is longer than the second wavelength range.

18. A light emitting device, comprising:
a light emitting component capable of radiating a light;
a first fluorescent layer capable of radiating a first light of a first wavelength range while being excited by the light;
a second fluorescent layer capable of radiating a second light of a second wavelength range while being excited by the light; and
a transparent layer disposed on the second fluorescent layer;
wherein a first fluorescent layer is between the light emitting component and the second fluorescent layer, and the first wavelength range is longer than the second wavelength range.
